(19) United States
(12) Patent Application Publication
(10) Pub. No.: US 2026/0353825 A1
(43) Pub. Date: Nov. 5, 2026

(54) ELECTRONIC MODULE AND ELECTRONIC EQUIPMENT

(71) Applicant: CANON KABUSHIKI KAISHA, Tokyo (JP)

(72) Inventors: TAKASHI NUMAGI, Tokyo (JP); SEIJI HAYASHI, Kanagawa (JP); YOUHEI TAZAWA, Kanagawa (JP)

(21) Appl. No.: 19/653,307

(22) Filed: Apr. 21, 2026

(30) Foreign Application Priority Data
Apr. 30, 2025 (JP) 2025-075460

(51) Int. Cl. H10F 39/18; H04N 1/00; H10B 80/00; H10F 39/00

(52) U.S. Cl. CPC H10F 39/1895; H04N 1/00907; H10B 80/00; H10F 39/811

(57) ABSTRACT

An electronic module includes a first electronic device, a second electronic device, and a substrate. The substrate includes a first conductive layer, a second conductive layer, and an interlayer insulating layer. A plurality of power feeding terminals included in the first electronic device are electrically connected to a plurality of first connection portions of a first pattern disposed in the first conductive layer. A conductive path including the second conductive layer and disposed through the interlayer insulating layer is electrically connected to a third connection portion of the first pattern. The first pattern and the second conductive layer form at least a part of a power feeding path for supplying power to the plurality of power feeding terminals included in the first electronic device.

### BACKGROUND

### Field of the Technology

The present disclosure relates to an electronic module on which a plurality of electronic devices are mounted, electronic equipment including the electronic module, and the like.

### DESCRIPTION OF THE RELATED ART

In recent electronic equipment, an electronic module in which a plurality of electronic devices are mounted on the same substrate is used for miniaturization and high functionality.

JP 2012-8695 A describes a memory module in which a plurality of memories are mounted on a module substrate. JP 2012-8695 A discloses a module socket and a signal wiring for supplying a signal to the plurality of memories mounted on the module substrate. Methods of routing and branching a CLK line, a CA line, a DQ (data) line, and a DQS (DQ strobe) line are disclosed.

### SUMMARY

One of the problems to be solved by the embodiments disclosed in the present specification and the drawings is stability of operation of a plurality of electronic devices in an electronic module including the plurality of electronic devices mounted on a substrate. However, the problems to be solved by the embodiments disclosed in the present specification and the drawings are not limited to the above problem. A problem corresponding to each effect achieved by each configuration described in the embodiments described below can also be regarded as another problem.

According to a first aspect of the present disclosure, an electronic module includes a first electronic device, a second electronic device, and a substrate having a first surface and a second surface opposite to the first surface. The first electronic device and the second electronic device are mounted on the first surface of the substrate. The substrate includes a first conductive layer, a second conductive layer disposed closer to the second surface than the first conductive layer, and an interlayer insulating layer disposed between the first conductive layer and the second conductive layer. A plurality of power feeding terminals included in the first electronic device are electrically connected to a plurality of first connection portions of a first pattern disposed in the first conductive layer. A plurality of power feeding terminals included in the second electronic device are electrically connected to a plurality of second connection portions of a second pattern disposed in the first conductive layer. A conductive path including the second conductive layer and disposed through the interlayer insulating layer is electrically connected to a third connection portion of the first pattern. A conductive path including the second conductive layer disposed through the interlayer insulating layer is electrically connected to a fourth connection portion of the second pattern. The first pattern and the second conductive layer form at least a part of a power feeding path for supplying power to the plurality of power feeding terminals included in the first electronic device. The second pattern and the second conductive layer form at least a part of a power feeding path for supplying power to the plurality of power feeding terminals included in the second electronic device.

Features of the present disclosure will become apparent from the following description of embodiments with reference to the attached drawings. The following description of embodiments is described by way of example.

### BRIEF DESCRIPTION OF THE DRAWINGS

FIG. 1 is an external perspective view illustrating an image forming apparatus which is electronic equipment including an electronic module according to an embodiment.

FIG. 2 is a schematic diagram for describing an example of an overall configuration of an image processing unit.

FIG. 3 is a schematic cross-sectional view of the periphery of a portion where the electronic module according to a first embodiment is mounted.

FIG. 4 is a schematic cross-sectional view illustrating a cross section of the electronic module according to the first embodiment.

FIG. 5 is a schematic diagram illustrating an arrangement of electrical connection terminals of a memory element.

FIG. 6 is a schematic diagram for describing supply paths for power and a signal to each memory element.

FIG. 7 is a schematic perspective view of a part of the electronic module according to the first embodiment as viewed from a direction perpendicular to a first surface of a module substrate.

FIG. 8 is a schematic diagram for describing a power feeding path according to a second embodiment.

FIG. 9 is a schematic perspective view of a part of an electronic module according to the second embodiment as viewed from a direction perpendicular to a first surface of a module substrate.

FIG. 10 is a schematic diagram for describing a power feeding path for power to each memory element of an electronic module according to a third embodiment.

FIG. 11 is a schematic view illustrating an arrangement of a pattern, a wiring, a connection portion connecting the pattern and the wiring, and a connection portion connecting a via and the wiring in the third embodiment.

FIG. 12 is a schematic perspective view of a part of the electronic module according to the third embodiment as viewed from a direction perpendicular to a first surface of a module substrate.

FIG. 13 is a schematic diagram illustrating supply paths for power and a signal to each memory element in the third embodiment.

### DESCRIPTION OF THE EMBODIMENTS

The present inventors have studied a method of supplying power to a plurality of electronic devices.

Examples of the electronic device include semiconductor elements such as a semiconductor memory, an image sensor, and a data processing processor. A relatively large-scale semiconductor element used in recent years includes a plurality of power feeding terminals, and a power supply voltage is supplied to a circuit disposed at each portion in the semiconductor element via the plurality of power feeding terminals. When there is a variation between voltages of power supplied to the plurality of power feeding terminals, an operation of the electronic device (semiconductor element) may become unstable due to variations in an operation of a circuit disposed at each portion in the electronic device.

In the present specification, a technology useful for reducing a variation in a power supply voltage supplied to each power feeding terminal of an electronic device in a case where a plurality of electronic devices including a plurality of power feeding terminals are mounted on a substrate is disclosed below.

An electronic module, electronic equipment, and the like according to embodiments will be described with reference to the drawings. The embodiments described below are merely examples, and for example, detailed configurations can be appropriately changed and implemented by those skilled in the art without departing from the technical idea.

In the drawings referred to in the following embodiments and description, elements denoted by the same reference signs have similar functions unless otherwise specified. In the drawings, in a case where a plurality of the same elements are arranged, reference signs and a description thereof may be omitted.

In addition, the drawings may be schematic for convenience of illustration and description, and thus, the shape, size, arrangement, and the like of elements in the drawings may not strictly match those of actual ones.

A relationship of “being substantially equal” used in the following description will be described. For example, while designed to be equal, slight differences may occur in practice due to unavoidable manufacturing errors. “Being substantially equal” includes a slight difference caused by such manufacturing errors or a tolerance set in design in advance.

### FIRST EMBODIMENT

### Electronic Equipment

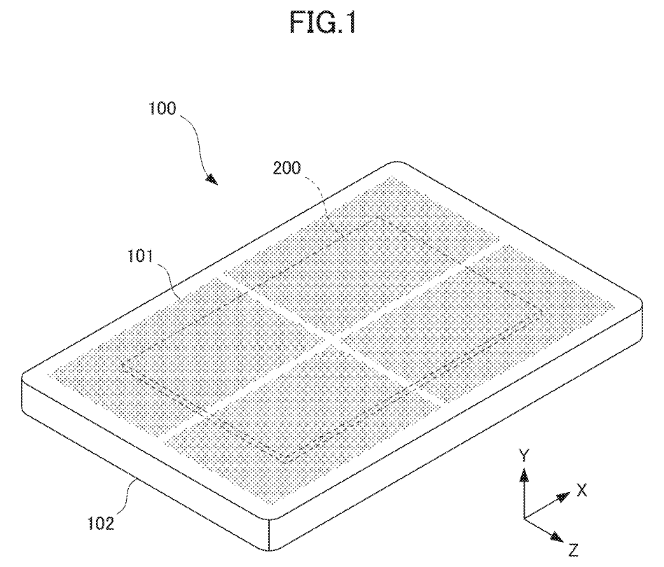

FIG. 1 is an external perspective view illustrating an image forming apparatus 100 serving as electronic equipment including an electronic module according to an embodiment. The electronic equipment including the electronic module according to the embodiment is not limited to the image forming apparatus, and may be various types of electronic equipment used for various applications such as industrial use, consumer use, and medical use. The image forming apparatus 100 is, for example, an X-ray flat panel detector and is used as medical equipment, and may also be another image forming apparatus such as a display device or a printing device.

The image forming apparatus 100 exemplified here is an apparatus that includes an apparatus body 101, an image processing unit 200, and a casing 102, and outputs image data corresponding to an electromagnetic wave such as an incident X-ray. The apparatus body 101 includes a scintillator, a photodiode, a transistor array, an analog-to-digital converter, a low noise amplifier, and the like (not illustrated). However, the apparatus body 101 may also be an apparatus body that directly photoelectrically converts an electromagnetic wave such as an X-ray by a light receiving element without including a scintillator.

The image processing unit 200 is connected to the apparatus body 101 so as to be able to transmit and receive an electrical signal, and the image data output from the apparatus body 101 is input to the image processing unit 200. The image processing unit 200 executes image processing on the input image data. Furthermore, the image processing unit 200 is configured to be able to transmit the image data to external equipment via an interface such as a local area network (LAN) or a universal serial bus (USB).

The electronic module according to the embodiment can be mounted on the apparatus body 101 or the image processing unit 200. The electronic module mounted on the apparatus body 101 can be, for example, an electronic module in which a plurality of sensor elements (electronic devices) are mounted on a substrate. The electronic module mounted on the image processing unit 200 can be, for example, an electronic module in which a plurality of memory elements are mounted on a substrate. Hereinafter, a case where the electronic module according to the embodiment is mounted on the image processing unit 200 will be described as an example.

### Image Processing Unit

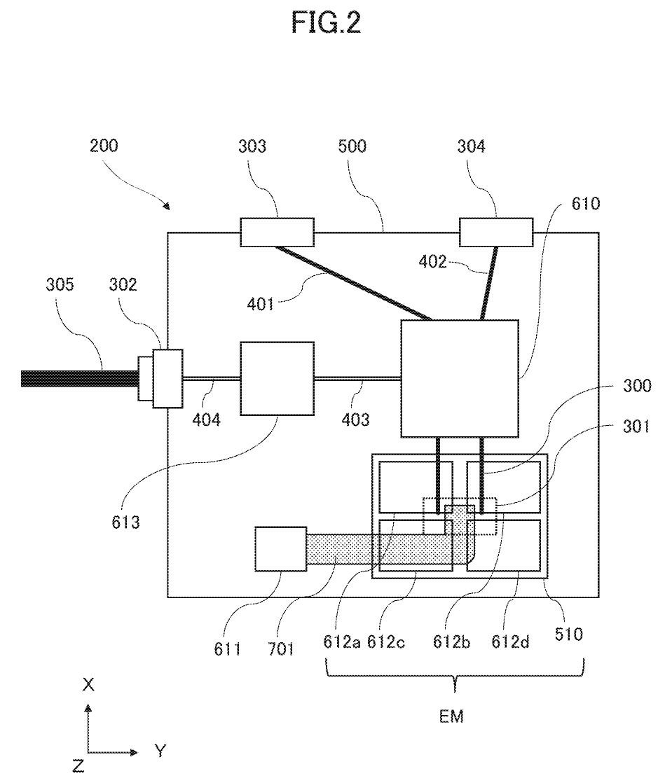

FIG. 2 is a schematic diagram for describing an example of an overall configuration of the image processing unit 200. The image processing unit 200 includes a memory controller 610 mounted on a printed wiring board 500, and electronic module EM according to the present embodiment, which is mounted on the printed wiring board 500 via a connector 301. The image processing unit 200 further includes a plurality of components mounted on the printed wiring board 500, namely, a connector 302, a connector 303, a connector 304, and a conversion chip 613.

The connector 303 and the connector 304 are connected to the apparatus body 101 via a wiring member (not illustrated) such as a cable or a flexible substrate. The image data is input from the apparatus body 101 to the connector 303 and the connector 304 via the wiring member such as a cable. In addition, the connector 303 and the connector 304 are electrically connected to the memory controller 610 via a wiring 401 and a wiring 402 of the printed wiring board 500. An image data signal input to the connector 303 is transmitted to the memory controller 610 via the wiring 401, and an image data signal input to the connector 304 is transmitted to the memory controller 610 via the wiring 402.

The conversion chip 613 is electrically connected to the connector 302 via a wiring 404 of the printed wiring board 500. A cable 305 is connected to the connector 302. The conversion chip 613 converts the image data transmitted from the memory controller 610 into a format defined in a communication standard. Further, the conversion chip 613 outputs the converted image data to the cable 305 via the wiring 404 and the connector 302. The cable 305 is a wiring member that connects an image processing board and the external equipment to each other, and is connected to, for example, a computer. The image data is input to the computer via the cable 305, and the computer executes display processing on a display, storage processing in a storage device, and the like.

The electronic module EM according to the embodiment is connected to the printed wiring board 500 via the connector 301. The electronic module EM is an electronic module in which a memory element 612a, a memory element 612b, a memory element 612c, and a memory element 612d serving as electronic devices are mounted on a module substrate 510.

The memory element 612a, the memory element 612b, the memory element 612c, and the memory element 612d mounted on the module substrate 510 transmit and receive data to and from the memory controller 610 via a connector 300. A power supply circuit 611 is mounted on the printed wiring board 500, and a power supply voltage output from the power supply circuit 611 is supplied to the module substrate 510 via a power supply wiring 701 and the connector 301 of the image processing unit 200.

The memory element 612a, the memory element 612b, the memory element 612c, and the memory element 612d included in the electronic module EM can be implemented by, for example, the same type of memory elements. As the memory elements 612a to 612d, for example, double data rate 4 (DDR4) memories are used, but the memory elements 612a to 612d may also be memories of other standards or types.

The memory controller 610 stores the image data in the memory elements 612a to 612d. In addition, the memory controller 610 reads the stored image data from the memory elements 612a to 612d. In addition, the memory controller 610 outputs the image data to the conversion chip 613 via a wiring 403.

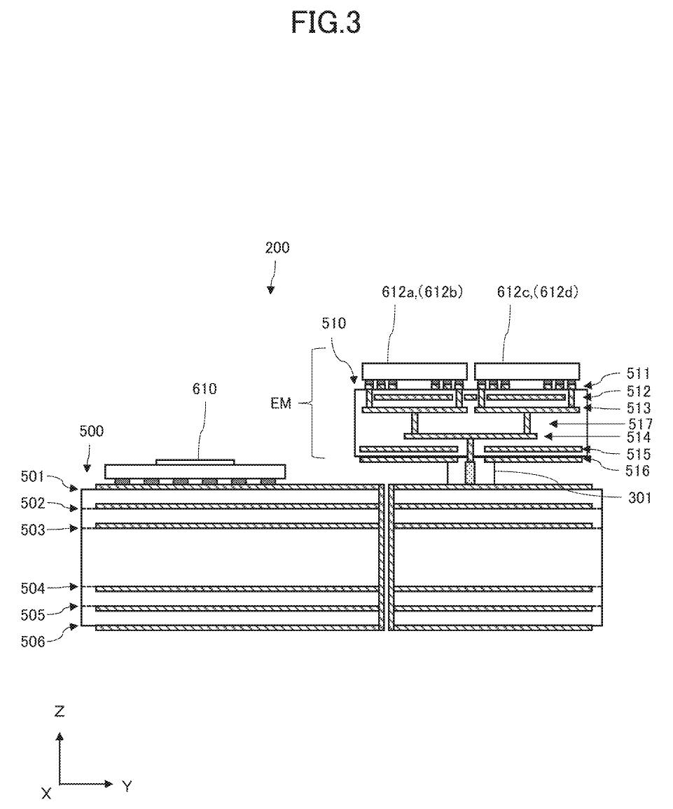

Next, a structure of the image processing unit 200 in which the electronic module EM according to the embodiment is mounted will be described. FIG. 3 illustrates a partial cross section of the image processing unit 200, and is a schematic cross-sectional view of the periphery of a portion where the electronic module EM according to the embodiment is mounted.

The electronic module EM includes the memory elements 612a to 612d mounted on one main surface of the module substrate 510 in order to store a large amount of image data handled by the X-ray flat panel detector. In addition, in order to reduce a thickness of the equipment, the connector 301 having a small height is disposed on the other main surface of the module substrate 510, and the module substrate 510 is attached to the printed wiring board 500 via the connector 301. The module substrate 510 is desirably a substrate that has a sufficient strength for mounting a plurality of electronic devices and is resistant to warpage and thermal expansion, such as a ceramic substrate.

Hereinafter, for convenience of description, in a multilayer wiring board such as the printed wiring board 500 or the module substrate 510, a wiring layer (conductive layer) disposed on one of two main surfaces of the substrate may be referred to as a front layer, and a wiring layer (conductive layer) disposed on the other of two main surfaces of the substrate may be referred to as a back layer. In addition, a wiring layer (conductive layer) disposed inside the substrate may be referred to as an inner layer.

The printed wiring board 500 is a multilayer substrate, and although a six-layer substrate is illustrated in FIG. 3, the number of layers is not limited thereto. A layer 501 is the front layer. Layers 502, 503, 504, and 505 are the inner layers. A layer 506 is the back layer. The memory controller 610 and the connector 301 are mounted on the layer 501 which is the front layer of the printed wiring board 500.

The memory controller 610 is electrically connected to the printed wiring board 500 by a solder, a socket, or the like. The memory controller 610 includes a plurality of signal terminals, a plurality of power supply terminals, and a plurality of ground terminals. The power supply terminal and the ground terminal are power feeding terminals. The terminals of the memory controller 610 form a ball grid array structure in which the terminals are arranged in a matrix. The connector 301 electrically and mechanically connects the module substrate 510 of the electronic module EM and the printed wiring board 500.

Here, the memory elements 612a to 612d serving as the electronic devices mounted on the module substrate 510 will be described. The memory elements 612a to 612d are memory elements having the same structure, and are, for example, DDR4-SDRAMs having a ball grid array structure in which electrical connection terminals are arranged in a matrix. In the following description, when it is not necessary to distinguish the four memory elements, the four memory elements may be referred to as the memory element 612. In addition, the memory element 612a may be referred to as a first electronic device, and the memory element 612c may be referred to as a second electronic device. However, this is for convenience of description, and any of the four memory elements may be referred to as a first electronic device or a second electronic device.

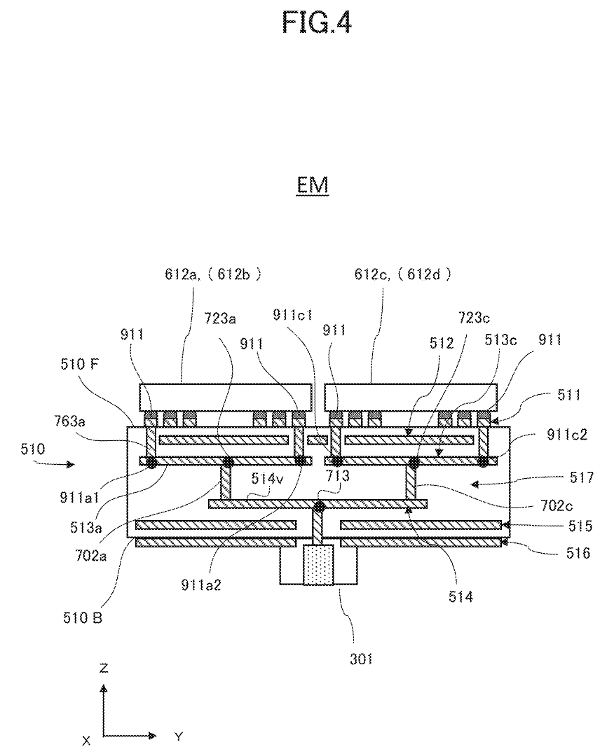

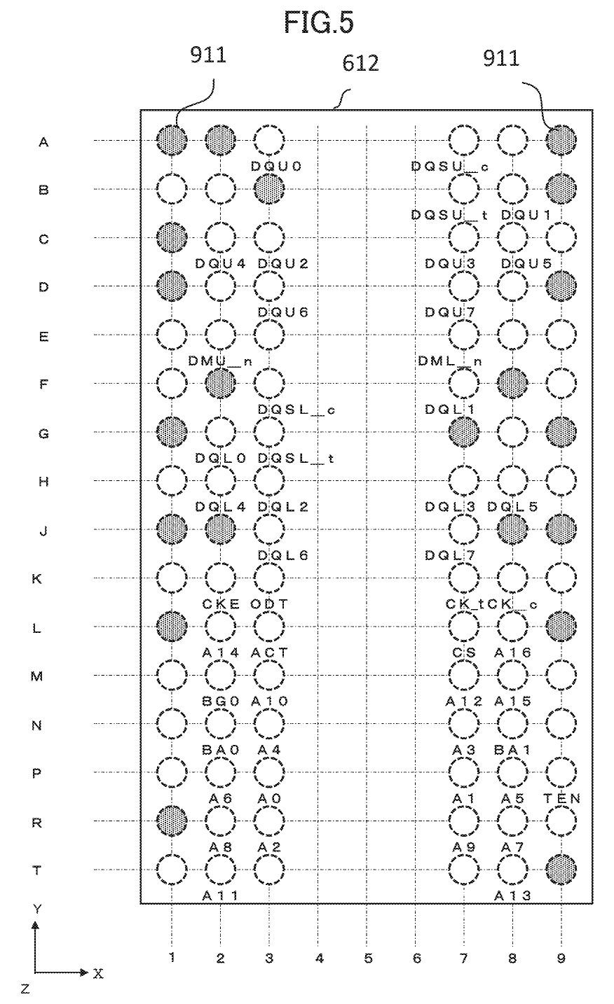

FIG. 5 is a schematic diagram illustrating an arrangement of the electrical connection terminals of the memory element 612. FIG. 5 illustrates a see-through view of the memory element 612 in a direction (Z direction) perpendicular to a first surface 510F in a state in which the memory element 612 is mounted on the first surface 510F (FIG. 4) of the module substrate 510. Each electrical connection terminal is indicated by a dashed circle. For convenience, 16 rows of A to T and nine columns of 1 to 9 are used to indicate positions of the electrical connection terminals.

As illustrated in FIG. 5, in a region divided into 16 rows × 9 columns, the electrical connection terminals are provided in the first to third columns and the seventh to ninth columns, and the electrical connection terminals are not provided in the fourth to sixth columns. The total number of electrical connection terminals is 96. The power supply voltage to be supplied to the DDR4-SDRAM is 1.2 V. In FIG. 5, the electrical connection terminal indicated by gray shading is a power feeding terminal 911 of 1.2 V. In the example, the memory element 612 is provided with 21 power feeding terminals 911. Command/address terminals which are control terminals of the memory element are CKE, CS, ODT, A0 to A16, BA0, BA1, BG0, ACT, PAR, and TEN. The command/address terminals are arranged in a range of the second to ninth columns in the K to T rows. Data terminals are DQU0 to DQU7 and DQL0 to DQL7. Data mask terminals are DMU_n and DML_n. Data strobe terminals are DQSU_c, DQSU_t, DQSL_c, and DQSL_t. The data terminal, the data mask terminal, and the data strobe terminal are arranged in a range of the second to eighth columns in the A to J rows. Clock terminals CK_t and CK_c are arranged in the seventh and eighth columns of the L row. The memory element 612 further includes an ALERT terminal, a RESET terminal, and a ground terminal (which are not illustrated).

It is a matter of course that a variation in the power supply voltage supplied to each of the four memory elements, that is, the memory elements 612a to 612d, needs to be suppressed in order to stabilize an operation of the electronic module EM. Therefore, a structure capable of suppressing a resistance variation between power supply wirings from the power supply circuit 611 to the memory elements 612a to 612d is required.

Furthermore, it is desirable that a variation between the power supply voltages supplied to 21 power feeding terminals 911 included in each of the memory elements 612a to 612d is small. This is because when the power supply voltages supplied to 21 power feeding terminals 911 vary, the operation of the memory element becomes unstable. The electronic device mounted on the substrate is not limited to the memory element described as an example, and in a case where another electronic device including a plurality of power feeding terminals is mounted on a substrate, it is effective to suppress a variation between the power supply voltages supplied to the respective power feeding terminals in order to stabilize the operation.

FIG. 4 is a schematic cross-sectional view illustrating a cross section of the electronic module EM according to the present embodiment. The electronic module EM includes the module substrate 510, the memory elements 612a to 612d, and the connector 301.

Of the main surfaces of the module substrate 510, the main surface on a side on which a layer 511 (front layer) is disposed is referred to as the first surface 510F, and the main surface on a side which is opposite to the first surface and on which a layer 516 (back layer) is disposed is referred to as a second surface 510B. As illustrated in FIG. 4, the module substrate 510 is a multilayer wiring board in which a plurality of conductor layers are stacked with an interlayer insulating layer interposed therebetween. Although a six-layer substrate is illustrated in FIG. 4, the number of conductive layers is not limited thereto. The layer 511 is the front layer. Layers 512, 513, 514, and 515 are the inner layers. The layer 516 is the back layer. The conductor layers are stacked with an interlayer insulating layer 517 interposed therebetween. Among the wiring layers, a wiring layer that forms a part of a power feeding path for supplying the power supply voltage to the power feeding terminal 911 included in the memory element 612 is referred to as a power supply wiring layer.

The memory elements 612a to 612d are mounted on the first surface 510F. In the layer 511 (front layer), terminals and signal wirings for mounting the respective memory elements are disposed. The memory elements 612a to 612d are connected to the terminals of the layer 511 (front layer) of the module substrate 510 by soldering. The layer 512 of the module substrate 510 is a ground plane layer in which a ground wiring pattern is formed.

The layer 513 is the power supply wiring layer and is referred to as a first conductive layer for convenience. In the layer 513 (first conductive layer), four conductors (patterns) respectively corresponding to the memory elements 612a to 612d are provided in order to supply power to each memory element. For example, a pattern 513a (first pattern) is provided at a position corresponding to the memory element 612a (first electronic device), and a pattern 513c (second pattern) is provided at a position corresponding to the memory element 612c (second electronic device). Similarly, a pattern is provided for each of the memory element 612b and the memory element 612d. A slit is provided in at least a part between adjacent patterns among the patterns 513a to 513d, and a part of the interlayer insulating layer is disposed in the slit. In other words, in the layer 513 (first conductive layer), each of the patterns 513a to 513d is divided by the slit.

The power feeding terminal 911 of each memory element is electrically connected to a corresponding pattern through a via passing through the interlayer insulating layer 517. As illustrated in FIG. 4, in the memory element 612a (first electronic device), one power feeding terminal 911 is connected to a first connection portion 911a1 of the pattern 513a (first pattern) through a via 763a, and another power feeding terminal 911 is connected to another first connection portion 911a2 of the pattern 513a (first pattern) through another via. In the memory element 612c (second electronic device), one power feeding terminal 911 is connected to a second connection portion 911c1 of the pattern 513c (second pattern) through a via, and another power feeding terminal 911 is connected to another second connection portion 911c2 of the pattern 513c (second pattern) through another via. Similarly, each of the power feeding terminals 911 of the memory element 612b and the memory element 612d is electrically connected to a corresponding pattern through a via.

The layer 514 is the power supply wiring layer and is referred to as a second conductive layer for convenience. The layer 514 (second conductive layer) is electrically connected to the pattern disposed in the layer 513 through a via passing through the interlayer insulating layer 517, and forms a part of a conductive path. For example, a conductive pattern 514v of the layer 514 is electrically connected to a connection portion 723a (third connection portion) of the pattern 513a (first pattern) through a via 702a (first via), and is electrically connected to a connection portion 723c (fourth connection portion) of the pattern 513c (second pattern) through a via 702c (second via). Similarly, the conductive pattern 514v is electrically connected to the pattern 513b and the pattern 513d individually through vias.

The layer 515 is a ground plane layer. The connector 301 is mounted on the second surface 510B of the module substrate 510, and the power supply circuit 611 (FIG. 2) is electrically connected to the connector 301.

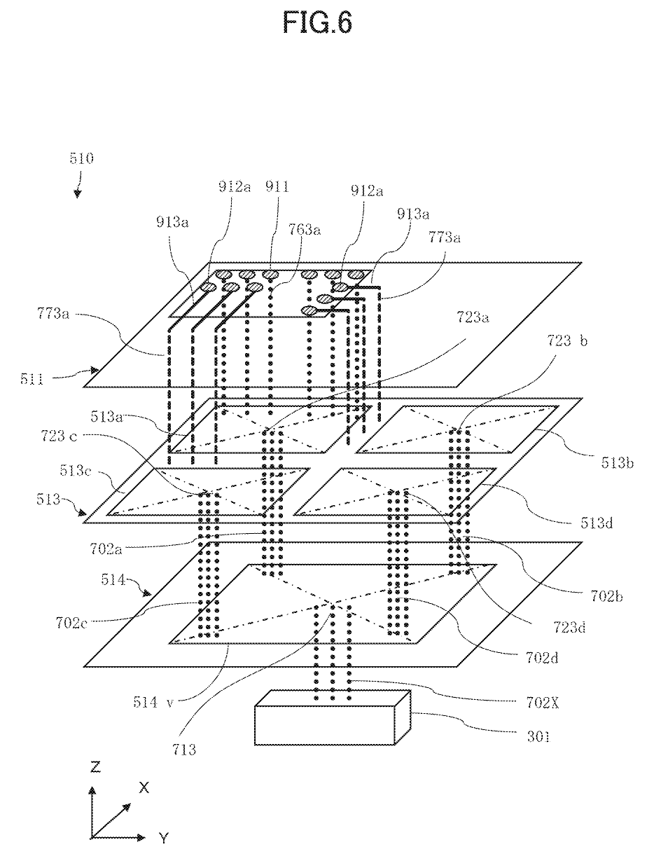

Supply paths for power and a signal to each memory element will be described with reference to FIG. 6. Although an arrangement of the terminals is illustrated only for the memory element 612a in order to avoid complication in the drawing, the terminals are similarly arranged for the memory elements 612b to 612d.

The power is supplied to the connector 301 from the power supply circuit 611 (FIG. 2) disposed outside the electronic module EM. The power supplied to the connector 301 is supplied to the conductive pattern 514v provided in the layer 514 through a via 702X. A connection portion 713 where the via 702X and the conductive pattern 514v are connected is disposed at a position at a substantially equal distance from all of the memory elements 612a to 612d in a see-through view of the electronic module EM in a direction perpendicular to the first surface 510F of the module substrate 510. The conductive pattern 514v may be a conductive layer having a predetermined film thickness, and may also be, for example, a conductive layer having a gap like a mesh pattern. An outer shape of the conductive pattern 514v may be, for example, a rectangle with the connection portion 713 as a center of gravity, and may also be any other shape.

In the layer 513 stacked on the layer 514 with the interlayer insulating layer 517 interposed therebetween, the patterns 513ato 513dare provided at positions respectively corresponding to the memory elements 612a to 612d. Each of the patterns 513a to 513d is electrically connected to the conductive pattern 514v through a via provided in the interlayer insulating layer 517. That is, the pattern 513a serving as the first pattern is connected to the via 702a at the connection portion 723a (third connection portion), and is electrically connected to the conductive pattern 514v through the via 702a. The number of vias 702a may be singular or plural. Similarly, the pattern 513b serving as a second pattern is connected to a via 702b at a connection portion 723b (fourth connection portion), and is electrically connected to the conductive pattern 514v through the via 702b. Similarly, the pattern 513c serving as a third pattern and the pattern 513d serving as a fourth pattern are also electrically connected to the conductive pattern 514v through vias, respectively.

The power feeding terminal 911 of the memory element 612a is electrically connected to the pattern 513a serving as the first pattern through the via 763a (FIG. 4) provided in the interlayer insulating layer 517. A terminal 912a (for example, a signal terminal or a ground terminal) of the memory element 612a excluding the power feeding terminal 911 is led out to a position not overlapping the pattern 513a via a wiring 913a provided in the layer 511, and is electrically connected to a signal wiring and a ground wiring of the connector 301 through a via 773a. The respective terminals of the memory elements 612b to 612d are also electrically connected in the same manner as the memory element 612a.

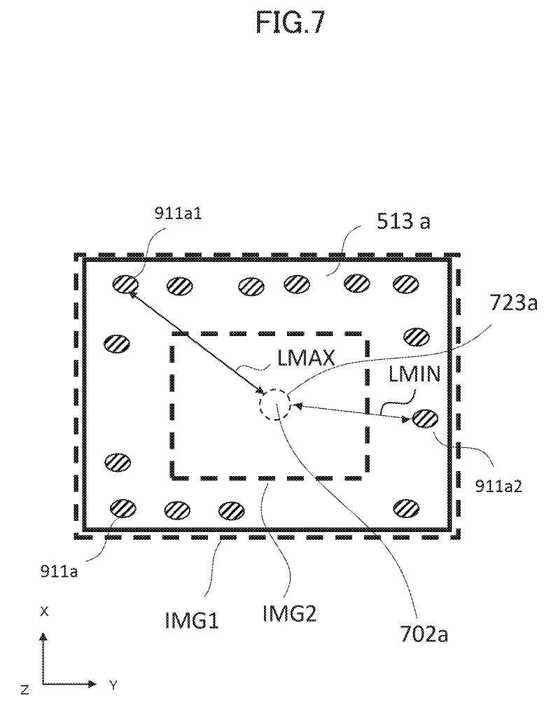

The feeding of the power to the plurality of power feeding terminals 911 included in the memory element 612a will be described with reference to FIG. 7. The power is supplied to the power feeding terminals of the memory elements 612b to 612d in the same manner as the memory element 612a. FIG. 7 is a schematic perspective view of a portion including the pattern 513a (first pattern) in the see-through view of the electronic module EM according to the embodiment in a direction perpendicular to the first surface 510F of the module substrate 510.

The plurality of power feeding terminals 911 included in the memory element 612a, the vias 763a, and the first connection portions 911a overlap in position and are indicated by hatched circles in FIG. 7, but are all disposed in the pattern 513a. In other words, the plurality of power feeding terminals 911 included in the memory element 612a (first electronic device) overlap the pattern 513a (first pattern) in a direction perpendicular to the first surface 510F.

The connection portion 723a (third connection portion) connecting the pattern 513a and the via 702a is disposed at a position substantially equal to the center of gravity of a planar shape of the pattern 513a. If the pattern 513ais rectangular, the connection portion 723a (third connection portion) is disposed at a position substantially equal to an intersection of diagonals.

As illustrated in FIG. 7, in the present embodiment, the connection portion 723a (third connection portion) is disposed at a position surrounded by the plurality of power feeding terminals (in other words, the plurality of first connection portions). In the pattern 513a, a wiring resistance corresponding to a distance exists between each first connection portion and the connection portion 723a. In the case of the two first connection portions 911a1 and 911a2 as illustrated in FIG. 4, a distance between one (first connection portion 911a1) of the two first connection portions 911a1 and 911a2 and the connection portion 723a is defined as La, and a distance between the other (first connection portion 911a2) of the two first connection portions 911a1 and 911a2 and the connection portion 723a is defined as Lb. A distance between one (first connection portion 911a1) of the two first connection portions 911a1 and 911a2 and the other (first connection portion 911a2) of the two first connection portions 911a1 and 911a2 is defined as Lc. It may be that a distance between the connection portion 723a and each of the two first connection portions 911a1 and 911a2 among the plurality of first connection portions is smaller (La < Lc and Lb < Lc) than the distance Lc between the two first connection portions 911a1 and 911a2. This is effective for suppressing variations in wiring resistance. The sum of the distance La and the distance Lb may be equal to or more than the distance Lc (La + Lb ≥ Lc). A difference between the distance La and the distance Lb may be smaller than the distance Lc (|La - Lb| < Lc). A difference between the distance La and the distance Lb may be smaller than the distance La (|La - Lb| < La). A difference between the distance La and the distance Lb may be smaller than the distance Lb (|La - Lb| < Lb). As illustrated in FIG. 7, among the plurality of first connection portions, a first connection portion that is farthest from the connection portion 723a can be set as the first connection portion 911a1, and a distance between the first connection portion 911a1 and the connection portion 723a can be defined as LMAX (La = LMAX). Among the plurality of first connection portions, a first connection portion that is closest to the connection portion 723a can be set as the first connection portion 911a2, and a distance between the first connection portion 911a2 and the connection portion 723a can be defined as LMIN (Lb = LMIN). In the present embodiment, LMAX - LMIN can be reduced by disposing the connection portion 723a at a position surrounded by the plurality of first connection portions. That is, it is possible to suppress variations in wiring resistance to the plurality of power feeding terminals 911 included in the same memory element. It may be that LMAX - LMIN < LMAX. All the first connection portions can be disposed at equal distances from the third connection portion, and in this case, it is sufficient to consider that LMIN = LMAX. The above-described two first connection portions are not limited to a combination of the first connection portion farthest from the connection portion 723a and the first connection portion closest to the connection portion 723a. For example, the above-described two first connection portions may be a combination of first connection portions that maximize the distance Lc, or a combination of first connection portions that minimize the distance Lc. Alternatively, a combination of first connection portions that make the distance Lc be a median value or an average value among all combinations of two connection portions among the plurality of first connection portions may be used. Here, the first connection portion and the third connection portion have been described, but the same applies to the second connection portion and the fourth connection portion. For example, referring to FIG. 4, the first connection portions 911a1 and 911a2 in the above description may be replaced with the second connection portions 911c1 and 911c2, and the third connection portion 723a may be replaced with the fourth connection portion 723c.

### Example 1

The module substrate 510 has dimensions of 31 mm × 19 mm and a thickness of 1.6 mm. On the module substrate, four memory elements having dimensions of 14.0 mm × 8.0 mm are tiled and mounted at intervals of 1.0 mm. In order to shorten a data wiring, the data terminal of the memory element is disposed so as to be close to the connector 301. The command/address terminals are disposed so as to be distant from the connector 301. In each pattern, the connection portion 723 is disposed at a position substantially equal to the center of gravity of the pattern.

A voltage drop in the power supply wiring up to the pattern and a voltage drop in the pattern are calculated. A simulator was used to calculate the voltage drop. First, the voltage drop in the power supply wiring including the conductive pattern 514vand the via 702 is calculated. A length of the power supply wiring is about 8.7 mm. A width of the conductive pattern 514v is 1 mm, and a thickness of the conductive pattern 514v is 0.005 mm. A material of the conductive pattern 514v is tungsten, and a conductivity thereof is about 1.0 × 10⁷ S/m. A resistance value of the power supply wiring is about 175.0 mΩ. When a current consumption of the memory element is 280.0 mA, the voltage drop in the power supply wiring is 49.0 mV.

Next, the voltage drop in the pattern 513a is calculated. The power supply wiring is connected to the center of the pattern 513a. The voltage drop is maximized at the first connection portions positioned at positions corresponding to four corners of the pattern 513a. In a terminal arrangement of the memory element illustrated in FIG. 5, the power feeding terminals A1, A9, R1, and T9 are connected to the first connection portions from approximately four corners of the pattern 513a through the vias 763a (FIG. 4). A distance between each of the power feeding terminals at the four corners and the center of the pattern 513a is about 6.8 mm. A thickness of the conductive layer of the pattern 513ais 0.005 mm. A conductivity thereof is about 1.0 × 10⁷ S/m. It is assumed that the respective current consumptions of the memory elements are equal to each other. The voltage drop from the center of the pattern 513ato the first connection portions at the four corners was calculated to be 2.5 mV. That is, an in-plane variation in voltage between the center and the four corners of the pattern 513a is 2.5 mV. Therefore, a voltage drop to the first connection portion at a position closer to the connection portion than to the four corners is less than 2.5 mV. As described above, in Example 1, the variation in power supply voltage supplied to the plurality of power feeding terminals disposed in the memory element via the pattern 513a is suppressed to be within 2.5 mV. For the voltage drop by the power supply wiring, for example, a voltage near the connection portion 723a may be detected and fed back to the power supply circuit 611 (FIG. 2) to correct a supply voltage.

### Modification of First Embodiment

In the above description, an example in which the connection portion 723a (third connection portion) is disposed at a position substantially equal to the center of gravity of the planar shape of the pattern 513a has been described in the first embodiment, but the position of the connection portion 723a is not limited thereto. For example, in a case where the plurality of first connection portions are arranged asymmetrically with respect to the position of the center of gravity of the pattern 513a, the connection portion 723a can be shifted from the position of the center of gravity of the pattern 513a as long as the connection portion 723a is disposed at a position surrounded by the plurality of first connection portions.

For example, the smallest imaginary quadrangle including the entire pattern 513a is an imaginary quadrangle IMG1 surrounded by a dotted line in FIG. 7, and a similar and smaller imaginary quadrangle having the same position of the center of gravity as the imaginary quadrangle IMG1 is an imaginary quadrangle IMG2 surrounded by a dotted line. The connection portion 723acan be disposed at an arbitrary position in the imaginary quadrangle IMG2. In this example, an area of the imaginary quadrangle IMG2 is 1/4 of an area of the imaginary quadrangle IMG1. The connection portion 723acan be disposed at an arbitrary position in the imaginary quadrangle IMG2.

Alternatively, the connection portion 723a (third connection portion) can be disposed at a position such that a distance from the center of gravity of the imaginary quadrangle IMG1 is shorter than 1/4 of a distance between the first connection portion 911a1 and the first connection portion 911a2 (that is, a distance between the first connection portions).

Also in the pattern 513c (second pattern), similarly, the connection portion 723c (fourth connection portion) can be disposed at a position where a distance from the center of gravity of the imaginary quadrangle IMG1 is shorter than 1/4 of a distance between the second connection portion 911c1 and the second connection portion 911c2 of the pattern 513c (second pattern) (that is, a distance between the second connection portions).

### Second Embodiment

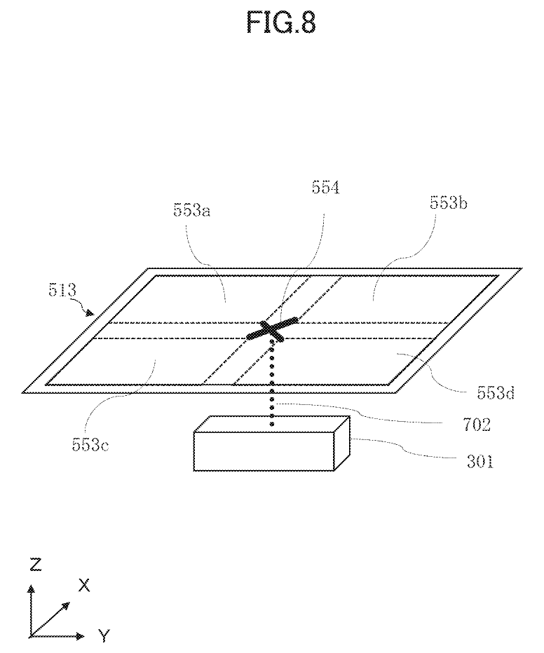

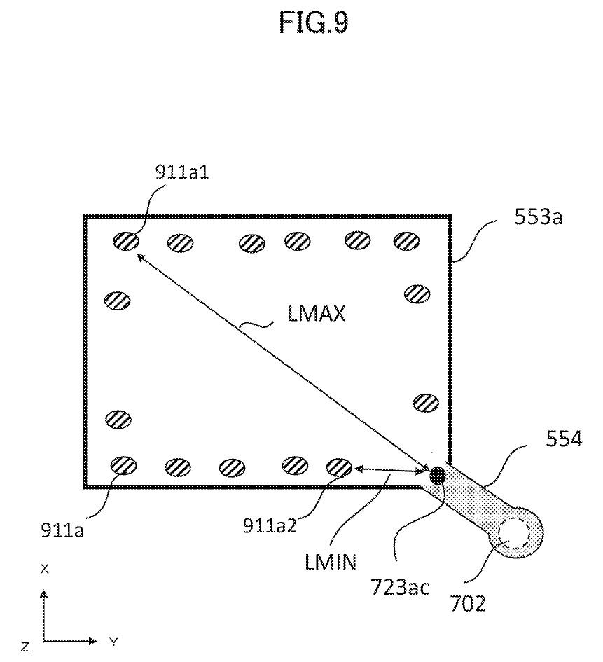

A second embodiment will be described with reference to FIGS. 8 and 9. A description of matters common to the first embodiment will be simplified or omitted. The basic configuration described with reference to FIGS. 1 and 2 is similar to that of the first embodiment. Similarly to the example in the first embodiment, a module substrate has a six-layer configuration, and a pattern corresponding to each memory element is disposed in a layer 513 of the module substrate. However, in order to distinguish from the first embodiment, in the second embodiment, the patterns are denoted by different reference signs 553a to 553d as illustrated in FIG. 8.

In the second embodiment, power is supplied to each of the patterns 553a to 553d through a via 702 and a wiring 554 provided in the layer 513. A straight line passing through the via 702 in a direction perpendicular to a first surface 510F is positioned between the patterns 553a to 553d. In such a configuration, by making a length of the wiring 554 from the via 702 to each pattern uniform, it is possible to suppress a variation in wiring resistance from the via 702 to connection points for the respective patterns. Therefore, also in the second embodiment, it is possible to suppress a variation in power supply voltage supplied to a plurality of memory elements for each memory element.

FIG. 9 is a view corresponding to FIG. 7 referred to in the first embodiment, and is a perspective view of a part including the pattern 553a in a see-through view of an electronic module EM in a direction perpendicular to the first surface 510F of a module substrate 510 in the second embodiment.

In the first embodiment, the connection portion 723a, which is a connection point to the pattern, is disposed at a position surrounded by the plurality of first connection portions, but in the second embodiment, a connection portion 723ac is provided on an outer edge (corner portion) of the pattern 553a in order to suppress the wiring resistance of the wiring 554. That is, in the second embodiment, the connection portion 723ac is disposed at a position not surrounded by a plurality of first connection portions 911a. Since the length of the wiring 554 of the layer 513 can be reduced as compared with the conductive pattern 514v of the layer 514 in the first embodiment (FIG. 4), a wiring resistance from a connector 301 to the connection portion 723ac (that is, the pattern 553a) can be reduced, and a voltage drop in such a portion can be suppressed.

Among the plurality of first connection portions, a distance between the connection portion 723ac and a first connection portion 911a2 closest to the connection portion 723ac is defined as LMIN, and a distance between the connection portion 723ac and a first connection portion 911a1 farthest from the connection portion 723ac is defined as LMAX. As can be seen by comparing FIGS. 7 and 9 , in the second embodiment, LMAX - LMIN is larger than that in the first embodiment. Therefore, as compared with the first embodiment, the second embodiment is less effective in suppressing a variation in wiring resistance to the plurality of power feeding terminals 911 included in the same memory element.

### Example 2

External dimensions of a module substrate and a memory element to be mounted are the same as those in Example 1. The pattern 553 has dimensions of 29.0 mm × 17.0 mm. As illustrated in FIG. 9, the connection portion 723ac is disposed at a corner of the pattern 553. When comparing the first connection portion 911a2 positioned closest to the connection portion 723ac with the first connection portion 911a1 positioned farthest from the connection portion 723ac, the difference (LMAX - LMIN) in distance from the connection portion 723acis about 14.9 mm. The voltage drop from the connection portion 723ac to the first connection portion 911a2 closest to the connection portion 723ac is 1.0 mV, and the voltage drop from the connection portion 723ac to the first connection portion 911a1 farthest from the connection portion 723ac is 6.2 mV. Therefore, in Example 2, a variation in power supply voltage supplied to the plurality of power feeding terminals disposed in the memory element was 6.2 (mV) - 1.0 (mV) = 5.2 (mV).

In Example 1, the variation in power supply voltage supplied to the plurality of power feeding terminals disposed in the memory element was suppressed to 2.5 mV, but in Example 2, the variation in power supply voltage was about 5.2 mV.

### Third Embodiment

An electronic module according to a third embodiment will be described. A description of matters common to the first embodiment will be simplified or omitted. The basic configuration described with reference to FIGS. 1 and 2 is similar to that of the first embodiment. Similarly to the example in the first embodiment, a module substrate has a six-layer configuration, and a pattern corresponding to each memory element is disposed in a layer 513 of the module substrate. However, the present embodiment is different from the first embodiment in a shape of the pattern and a configuration of a power feeding path connecting a connector 301 to each pattern.

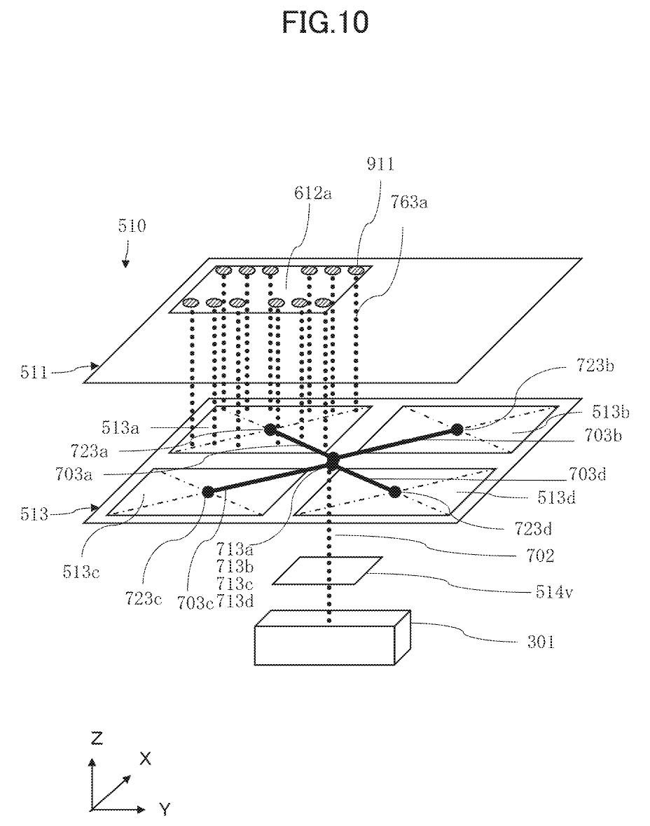

The power feeding path for power to each memory element in the third embodiment will be described with reference to FIG. 10. Although an arrangement of power feeding terminals 911 is illustrated only for a memory element 612a in order to avoid complication in the drawing, the power feeding terminals are similarly arranged also for memory elements 612b to 612d.

In the first embodiment, as illustrated in FIG. 6, the patterns 513a to 513d arranged in the layer 513 of the module substrate are connected to the vias 702a to 702d at the connection portions 723 arranged at positions substantially equal to the centers of gravity of the respective patterns. On the other hand, in the present embodiment, as illustrated in FIG. 10, power is supplied to each of patterns 513a to 513d through the via 702 and wirings 703a to 703d provided in the layer 513. A straight line passing through the via 702 in a direction perpendicular to a first surface 510F is positioned between the patterns 513a to 513d. In addition, in the second embodiment described with reference to FIGS. 8 and 9, power is supplied to each of the patterns 553a to 553d through the via 702 and the wiring 554 provided in the layer 513. However, the present embodiment is different from the second embodiment in a configuration of a connection portion between the wiring and the pattern provided in the layer 513. Although a single via 702 is illustrated in the drawing, a plurality of vias 702 may be disposed in the vicinity of the illustrated position.

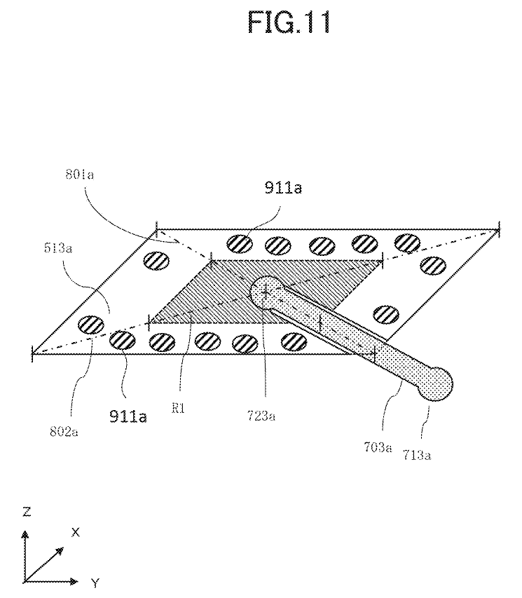

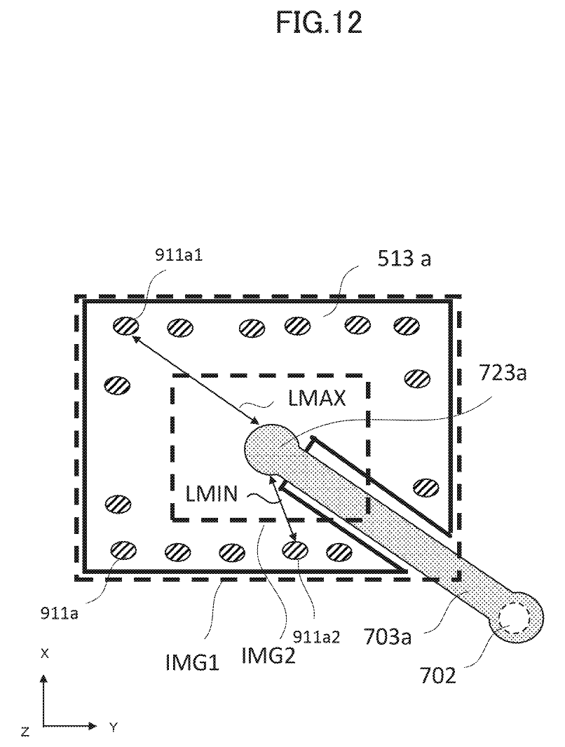

The feeding of the power to the plurality of power feeding terminals 911 included in the memory element 612a will be described with reference to FIGS. 11 and 12. The power is supplied to the power feeding terminals of the memory elements 612b to 612d in the same manner as the memory element 612a.

FIG. 11 is a schematic view illustrating an arrangement of the pattern 513a (first pattern), the wiring 703a, a connection portion 723a (third connection portion) that connects the pattern 513a and the wiring 703a, a connection portion 713a that connects the via 702 and the wiring 703a, and a first connection portion 911a1 that is connected to the power feeding terminal 911 of the memory element through a via 763a. FIG. 12 is a schematic perspective view of a part of an electronic module EM according to the third embodiment as viewed from a direction perpendicular to the first surface 510F of the module substrate 510.

As illustrated in FIGS. 11 and 12, a supply path for power through the via 702 and the wiring 703a is connected to the pattern 513a at the connection portion 723a. All of the plurality of power feeding terminals 911 included in the memory element 612a are disposed in the pattern 513a. In other words, the plurality of power feeding terminals 911 included in the memory element 612a (first electronic device) overlap the pattern 513a (first pattern) in a direction perpendicular to the first surface 510F.

In the present embodiment, unlike the second embodiment, the connection portion 723a connecting the pattern 513a and the wiring 703a is disposed at a position substantially equal to the center of gravity of a planar shape of the pattern 513a, instead of at a corner of the pattern 513a. However, in the present embodiment, the pattern 513a is not a rectangle as in the second embodiment, but has a shape in which a notch for disposing the wiring 703a is provided in a rectangle. Therefore, instead of being disposed at a position substantially equal to the center of gravity of the planar shape of the pattern 513a, the connection portion 723a may be disposed at a position substantially equal to the center of gravity of an imaginary quadrangle IMG1. Here, the imaginary quadrangle IMG1 is the smallest imaginary quadrangle including the entire pattern 513a.

In addition, a similar and smaller imaginary quadrangle having the same position of the center of gravity as the imaginary quadrangle IMG1 may be set as an imaginary quadrangle IMG2, and the connection portion 723a may be disposed inside the imaginary quadrangle IMG2. In the example illustrated in FIG. 12, an area of the imaginary quadrangle IMG2 is 1/4 of an area of the imaginary quadrangle IMG1. The connection portion 723a can be disposed at an arbitrary position in the imaginary quadrangle IMG2.

Alternatively, the connection portion 723a can be disposed at a position such that a distance from the center of gravity of the imaginary quadrangle IMG1 is shorter than 1/4 of a distance between the first connection portion 911a1 and the first connection portion 911a2 (that is, a distance between the first connection portions).

Also in the pattern 513c (second pattern), similarly, the connection portion 723c (fourth connection portion) can be disposed at a position where a distance from the center of gravity of the imaginary quadrangle IMG1 is shorter than 1/4 of a distance between the second connection portion 911c1 and the second connection portion 911c2 of the pattern 513c (second pattern) (that is, a distance between the second connection portions).

As illustrated in FIG. 12, in the present embodiment, the connection portion 723a is disposed at a position surrounded by the plurality of first connection portions. In the pattern 513a (first pattern), a wiring resistance corresponding to a distance exists between each first connection portion and the connection portion 723a. Among the plurality of first connection portions, a distance between the connection portion 723a and a first connection portion 911a2 closest to the connection portion 723a is defined as LMIN, and a distance between the connection portion 723a and a first connection portion 911a1 farthest from the connection portion 723a is defined as LMAX. In the present embodiment, LMAX - LMIN can be reduced by disposing the connection portion 723a at a position surrounded by the plurality of first connection portions. That is, it is possible to suppress variations in wiring resistance to the plurality of power feeding terminals 911 included in the same memory element. Therefore, according to the present embodiment, it is possible to reduce LMAX - LMIN as compared with the second embodiment described with reference to FIG. 9, and it is possible to suppress a variation in power supply voltage supplied to the respective power feeding terminals 911.

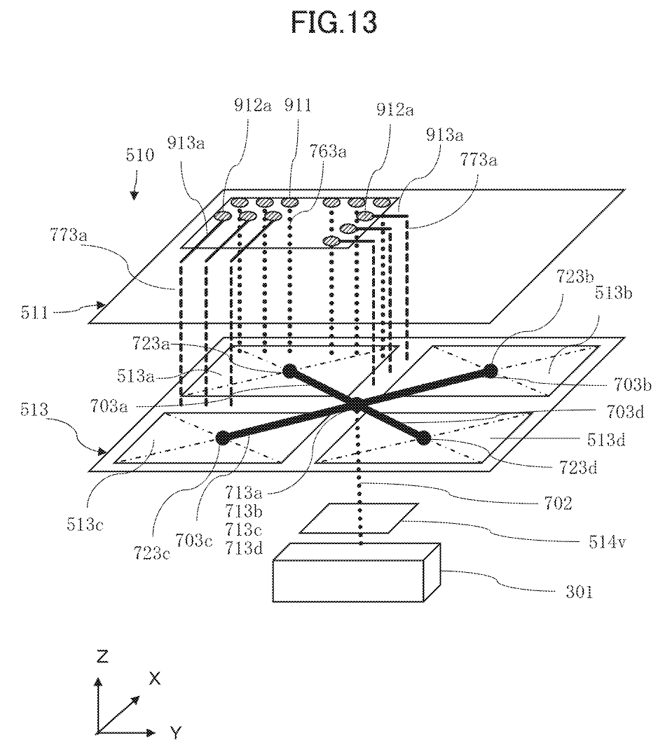

FIG. 13 is a schematic diagram illustrating supply paths for power and a signal to each memory element in the third embodiment. Although the power feeding terminal and a signal terminal are illustrated only for a memory element 612a in order to avoid complication in the drawing, the terminals are similarly arranged also for memory elements 612b to 612d.

The power feeding terminal 911 of the memory element 612a is electrically connected to the pattern 513a serving as the first pattern through the via 763a provided in an interlayer insulating layer 517. A terminal 912a(for example, a signal terminal or a ground terminal) of the memory element 612a excluding the power feeding terminal 911 is led out to a position not overlapping the pattern 513a via a wiring 913a provided in a layer 511, and is electrically connected to a signal wiring and a ground wiring of a connector 301 through a via 773a.

### Modified Embodiment

The present disclosure is not limited to the embodiments and examples described above, and many modifications can be made within the technical idea of the present disclosure. For example, all or some of the different embodiments and examples described above may be combined and implemented.

The pattern provided in the layer 513 corresponding to each memory element (electronic device) may have, for example, a rectangular shape as in the first embodiment and the second embodiment, a rectangular shape having a notch as in the third embodiment, or other shapes. The pattern may be formed of a solid (solid-plane) conductive film or a conductive film having voids like a mesh. In FIGS. 6 and 13, the signal terminal other than the power feeding terminal is wired through the via 773a outside the pattern of the layer 513, but an opening may be provided in the pattern and the via 773amay be disposed in the opening.

The plurality of electronic devices mounted on the module substrate is not limited to semiconductor memories of a DRAM. The semiconductor memory may be a flash memory. It is sufficient if the electronic device is an electronic device including a plurality of power feeding terminals, and the electronic device may be, for example, a sensor element such as an optical sensor or a mechanical sensor, a display element such as a liquid crystal or an organic EL, or a data processing processor. A plurality of semiconductor chips called chiplets may be mounted on the same substrate. The plurality of electronic devices may be different types of electronic devices.

Although an example in which four electronic devices are mounted on the first surface of the module substrate has been described, the number of electronic devices to be mounted is not particularly limited as long as it is plural, and may be, for example, two.

Electronic equipment including an electronic module according to the present disclosure and a support that supports the electronic module is also included in the embodiment. The electronic equipment according to the embodiment can be any of video equipment having an imaging function, video equipment having a display function, printing equipment, industrial equipment, and medical equipment.

Furthermore, the contents of disclosure in the present specification include not only contents described in the present specification but also all of the items which are understandable from the present specification and the drawings accompanying the present specification. Moreover, the contents of disclosure in the present specification include a complementary set of concepts described in the present specification. Thus, if, in the present specification, there is a description indicating that, for example, "A is B", even when a description indicating that "A is not B" is omitted, the present specification can be said to disclose a description indicating that "A is not B". This is because, in a case where there is a description indicating that "A is B", taking into consideration a case where "A is not B" is a premise.

### Other Embodiments

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-075460, filed Apr. 30, 2025, which is hereby incorporated by reference herein in its entirety.

What is claimed is:

1. An electronic module comprising:
a first electronic device;
a second electronic device; and
a substrate having a first surface and a second surface opposite to the first surface, wherein
the first electronic device and the second electronic device are mounted on the first surface of the substrate,
the substrate includes a first conductive layer, a second conductive layer disposed closer to the second surface than the first conductive layer, and an interlayer insulating layer disposed between the first conductive layer and the second conductive layer,
a plurality of power feeding terminals included in the first electronic device are electrically connected to a plurality of first connection portions of a first pattern disposed in the first conductive layer,
a plurality of power feeding terminals included in the second electronic device are electrically connected to a plurality of second connection portions of a second pattern disposed in the first conductive layer,
a conductive path including the second conductive layer and disposed through the interlayer insulating layer is electrically connected to a third connection portion of the first pattern,
a conductive path including the second conductive layer disposed through the interlayer insulating layer is electrically connected to a fourth connection portion of the second pattern,
the first pattern and the second conductive layer form at least a part of a power feeding path for supplying power to the plurality of power feeding terminals included in the first electronic device, and
the second pattern and the second conductive layer form at least a part of a power feeding path for supplying power to the plurality of power feeding terminals included in the second electronic device.

2. The electronic module according to claim 1, wherein
the plurality of power feeding terminals included in the first electronic device overlap the first pattern in a direction perpendicular to the first surface,
the third connection portion is surrounded by the plurality of first connection portions,
the plurality of power feeding terminals included in the second electronic device overlap the second pattern in the direction perpendicular to the first surface, and
the fourth connection portion is surrounded by the plurality of second connection portions.

3. The electronic module according to claim 1, wherein
the plurality of power feeding terminals included in the first electronic device overlap the first pattern in a direction perpendicular to the first surface,
a distance between the third connection portion and one first connection portion among the plurality of first connection portions and a distance between the third connection portion and another one first connection portion among the plurality of first connection portions are smaller than a distance between the one first connection portion and the another one first connection portion ,
the plurality of power feeding terminals included in the second electronic device overlap the second pattern in the direction perpendicular to the first surface, and
a distance between the fourth connection portion and one second connection portion among the plurality of second connection portions and a distance between the fourth connection portion and another one second connection portion among the plurality of second connection portions are smaller than a distance between the one second connection portion and the another one second connection portion.

4. The electronic module according to claim 3, wherein the one first connection portion is a first connection portion farthest from the third connection portion or a first connection portion closest to the third connection portion among the plurality of first connection portions.

5. The electronic module according to claim 3, wherein the one first connection portion is a first connection portion farthest from the third connection portion among the plurality of first connection portions, and the another one first connection portions is a first connection portion closest to the third connection portion among the plurality of first connection portions.

6. The electronic module according to claim 1, wherein
the third connection portion is disposed inside an imaginary quadrangle which is similar to a smallest imaginary quadrangle including the entire first pattern, the imaginary quadrangle having the same center of gravity as a center of gravity of the smallest imaginary quadrangle, the imaginary quadrangle having an area of 1/4 of an area of the smallest imaginary quadrangle, and
the fourth connection portion is disposed inside an imaginary quadrangle which is similar to a smallest imaginary quadrangle including the entire second pattern, the imaginary quadrangle having the same center of gravity as a center of gravity of the smallest imaginary quadrangle, the imaginary quadrangle having an area of 1/4 of an area of the smallest imaginary quadrangle.

7. The electronic module according to claim 1, wherein
in a see-through view of the electronic module in a direction perpendicular to the first surface,
the third connection portion is disposed at a position where a distance from a center of gravity of a smallest imaginary quadrangle including the entire first pattern is shorter than 1/4 of a distance between one first connection portion and another one first connection portion among the plurality of first connection portions, and
the fourth connection portion is disposed at a position where a distance from a center of gravity of a smallest imaginary quadrangle including the entire second pattern is shorter than 1/4 of a distance between one second connection portion and another one second connection portion among the plurality of second connection portions.

8. The electronic module according to claim 1, wherein
the first pattern and the second conductive layer are connected through a via passing through the interlayer insulating layer, and
a straight line passing through the via in a direction perpendicular to the first surface is positioned between the first pattern and the second pattern.

9. The electronic module according to claim 1, wherein
the first pattern and the second conductive layer are connected via a first via passing through the interlayer insulating layer,
the second pattern and the second conductive layer are connected via a second via passing through the interlayer insulating layer,
the first via overlaps the first pattern in a direction perpendicular to the first surface, and
the second via overlaps the second pattern in a direction perpendicular to the first surface.

10. The electronic module according to claim 9, wherein
the first via is any one of a plurality of vias overlapping the first pattern in a direction perpendicular to the first surface and electrically connected to the first pattern, and
the second via is any one of a plurality of vias overlapping the second pattern in a direction perpendicular to the first surface and electrically connected to the second pattern.

11. The electronic module according to claim 1, wherein the second conductive layer is electrically connected to a power supply disposed outside the substrate.

12. The electronic module according to claim 1, wherein a connector configured to supply power from an outside is attached to the substrate on a side opposite to the first surface.

13. The electronic module according to claim 8, wherein the second conductive layer has a conductive pattern configured to supply, to the via, a power supplied to the substrate via a connector disposed on the second surface.

14. The electronic module according to claim 9, wherein the second conductive layer has a conductive pattern configured to supply, to the first via and the second via, a power supplied to the substrate via a connector disposed on the second surface.

15. Electronic equipment comprising:
the electronic module according to claim 1; and
a support configured to support the electronic module.

16. The electronic equipment according to claim 15, wherein the electronic equipment is any one of video equipment, printing equipment, industrial equipment, and medical equipment.
